(19) United States
(12) Patent Application Publication
(10) Pub. No.: US 2017/0331496 A1
(43) Pub. Date: Nov. 16, 2017

(54) DECODING METHOD AND DECODER FOR LOW DENSITY PARITY CHECK CODE

(71) Applicant: National Tsing Hua University, Hsinchu City (TW)

(72) Inventors: Huang-Chang Lee, Taoyuan City (TW); Yeong-Luh Ueng, Hsinchu City (TW); Chin-Liang Wang, Hsinchu City (TW)

(21) Appl. No.: 15/203,440

(22) Filed: Jul. 6, 2016

(30) Foreign Application Priority Data
May 12, 2016 (TW) 105114682

(51) Int. Cl. H03M 13/11; H03M 13/00

(52) U.S. Cl. CPC H03M 13/1111; H03M 13/114; H03M 13/616

(57) ABSTRACT

A decoding method for low density parity check (LDPC) code, used to decode an input signal into a correct codeword according to a predetermined LDPC matrix, is provided. The method includes performing a plurality of decoding attempts according to the LDPC matrix within a predetermined number of decoding attempts, the plurality of decoding attempts at least including a first decoding attempt with use of a first decoding schedule and a second decoding attempt with use of a second decoding schedule. The second decoding attempt is adjacently subsequent to the first decoding attempt. The first decoding schedule as a group is not included in the second decoding schedule.

### CROSS-REFERENCE TO RELATED APPLICATION

This application claims the priority benefit of Taiwan application serial no. 105114682, filed on May 12, 2016. The entirety of the above-mentioned patent application is hereby incorporated by reference herein and made a part of this specification.

### BACKGROUND OF THE INVENTION

### 1. Field of the Invention

The invention relates to a decoding method and a decoder for low density parity check code, and more particularly, relates to a decoding method and a decoder for low density parity check code with a variable decoding schedule.

### 2. Description of Related Art

Low density parity check code (LDPC code) was proposed by Gallager in year 1962 and proven to have the error correcting capability very close to the theoretical maximum (the Shannon Limit) despite the lack of specific methods of implementation at the time.

In recent years, decoding approaches for LDPC code have been reconsidered in response to modern technical requirements in research and development of wireless communication. Modern technical requirements may include, for example, a video requirement with the demand of transmitting a large amount of data. With the assistance of a parallel data signal transmission adopted for transmitting the large amount of data, wireless communication devices can receive the correct data more rapidly. Further, in the case of mobile wireless communication devices, it can even help to lock on mobile wireless communication devices in fast motion (e.g., while driving) during communication. In addition, the parallel data signal transmission method is also suitable for optical transport, such as applications in ultra-high-speed serial optical transport networks. LDPC code has become a channel coding standard for various advanced communication systems ever since specific methods of implementation for LDPC code are feasible nowadays with advancements in IC technology.

Nonetheless, multiple decoding approaches have also been proposed mainly based on the iterative belief propagation (BP) for decoding LDPC code according to encoding approaches for LDPC matrix. However, a sequence of array elements in LDPC matrix is generally adopted as a decoding schedule used in decoding attempts with multiple iterations in the traditional approach.

When taking decoding efficiency into consideration, although the implementation of this type of decoding approach with fixed decoding schedule can be simply carried out, improvements on decoding efficiency are still the major concern for research and development team in the related field.

### SUMMARY OF THE INVENTION

The invention is directed to a decoding method and a decoder for low density parity check (LDPC) code, which are used to effectively decode an input signal into a correct codeword according to a predetermined LDPC matrix so as to accelerate a convergence speed for iterative operation.

A decoding method for LDPC code of the invention is used to decode an input signal into a correct codeword according to a predetermined LDPC matrix. The method includes performing a plurality of decoding attempts according to the LDPC matrix within a predetermined number of decoding attempts, the plurality of decoding attempts at least including a first decoding attempt with use of a first decoding schedule and a second decoding attempt with use of a second decoding schedule. The second decoding attempt is adjacently subsequent to the first decoding attempt. The first decoding schedule as a group is not included in the second decoding schedule.

A decoder for LDPC code of the invention is used to decode an input signal into a correct codeword according to a predetermined LDPC matrix, and includes: a decoding unit, configured to decode the input signal into the correct codeword according to the predetermined LDPC matrix, wherein a plurality of decoding attempts is performed according to the LDPC matrix within a predetermined number of decoding attempts, the plurality of decoding attempts at least including a first decoding attempt with use of a first decoding schedule and a second decoding attempt with use of a second decoding schedule, wherein the second decoding attempt is adjacently subsequent to the first decoding attempt, and the first decoding attempt is not included in the second decoding attempt; and a decoding schedule estimation unit, configured to generate and store a plurality of different decoding schedules according to the LDPC matrix for the decoding unit to obtain the first decoding schedule and the second decoding schedule.

According to an embodiment of the invention, in the decoding method and the decoder for LDPC code, the first decoding schedule is one of a layered belief propagation (LBP) sequence and a shuffled belief propagation (SBP) sequence, and the second decoding schedule is another one of the LBP sequence and the SBP sequence.

According to an embodiment of the invention, in the decoding method and the decoder for LDPC code, the first decoding schedule and the second decoding schedule are both the LBP sequence but the a code rate of the second decoding schedule is lower than a code rate of the first decoding schedule.

According to an embodiment of the invention, in the decoding method and the decoder for LDPC code, the first decoding schedule and the second decoding schedule are both the SBP sequence but the a code rate of the second decoding schedule is lower than a code rate of the first decoding schedule.

According to an embodiment of the invention, in the decoding method and the decoder for LDPC code, the first decoding schedule and the second decoding schedule are different sequences determined according to different parameter conditions on basis of a maximum mutual information increase (M²I²) algorithm.

According to an embodiment of the invention, in the decoding method and the decoder for LDPC code, the first decoding attempt and the second decoding attempt both reset an initial value of the codeword, or the subsequent second decoding attempt uses a result of the first decoding attempt as the initial value.

According to an embodiment of the invention, in the decoding method and the decoder for LDPC code, a code rate of the second decoding attempt is lower than a code rate of the first decoding attempt.

According to an embodiment of the invention, in the decoding method and the decoder for LDPC code, the first decoding schedule and the second decoding schedule are randomly arranged.

Based on the above, a plurality of decoding attempts may be included in the decoding process for a rate-compatible LDPC code. As a result, a faster convergence speed may be obtained by using different decoding schedules in the two adjacent decoding attempts, or a higher throughput may be obtained within the same number of iterations.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a LDPC matrix according to an embodiment of the invention.

FIG. 2 is a schematic diagram illustrating connections between the check nodes and the variable nodes according to the LDPC matrix of FIG. 1.

FIG. 3 is a schematic diagram illustrating a general planning of the LDPC matrix according to an embodiment of the invention.

FIG. 4 is a schematic diagram illustrating a mechanism of resetting each time in a M²I²-based decoding schedule adopted for decoding LDPC code according to an embodiment of the invention.

FIG. 5 is a schematic diagram illustrating a mechanism of incremental decoding schedules in a M²I²-based decoding schedule adopted for decoding the LDPC code according to an embodiment of the invention.

FIG. 6 is a flowchart of the decoding method for LDPC code according to an embodiment of the invention.

FIG. 7 is a schematic diagram illustrating structure of the decoder for LDPC code according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In connection with the decoding method and the decoder for LDPC code, the invention proposes to at least include two consecutive iterative decoding operations for decoding codewords. Different decoding schedules may be used to effectively use partial information already decoded and accumulated from the previous decoding operation in the subsequent iterative decoding operation to accelerate a convergence speed for iterative operation, or obtain a higher throughput within the same number of iterations.

The invention proposes a planning of the decoding schedules for improving decoding efficiency. Nevertheless, for the determined decoding schedules, the invention is not limited by use of any specific decoding approach operated at the back-end. In other words, under the premise of one given decoding schedule, for example, any applicable known decoding mechanism (including operations of hardware and/or software) may be adopted for decoding. That is to say, these decoding approaches for LDPC code can adopt the existing technologies in conventional art or future technologies which are still under development. Nevertheless, the invention aims to determine and provide the planning of the decoding schedules required for decoding LDPC code.

Embodiments are provided below to describe the invention in more detail, but the invention is not limited by the provided embodiments.

FIG. 1 is a schematic diagram illustrating a LDPC matrix according to an embodiment of the invention. Referring to FIG. 1, LDPC code is formed based on a parity check matrix with a property of sparse matrix. For an LDPC code in (n, k), every k-bit data is coded by an n-bit codeword. The following is an example of a parity check matrix H used by a LDPC code in (9, 6), as shown by FIG. 1. Among elements within the H matrix, the number of array elements “1” is far less than the number of array elements “0”. This is so-called the property of sparse matrix where the term “low density” is originated from.

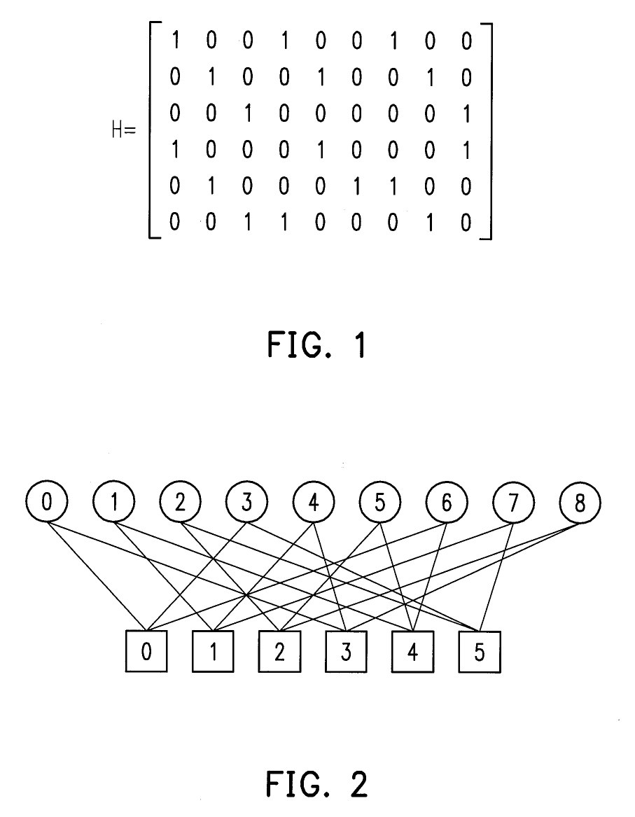

FIG. 2 is a schematic diagram illustrating connections between the check nodes and the variable nodes according to the LDPC matrix of FIG. 1. Referring to FIG. 2, the decoding approach for LDPC code may be represented corresponding to a bipartite graph. The bipartite graph is constructed according to said parity check matrix H, where a column of H corresponds to a check node (C) and a row of H corresponds to a bit node. The bit node is also known as a variable node. There is a connection relation (also known as an edge) between the check node and the variable node as determined by the matrix H (specifically, determined by the array element “1” within the matrix H).

In other words, among values of one column in the matrix H, the array element “1” means that it includes a connection to a corresponding variable node among the n variable nodes, whereas the array element “0” means it includes no such connection. Taking FIGS. 1 and 2 for example, values of the first row [100100100] describes the connection relations of the first check node to the variable nodes. Therefore, it can be known that a 0^{th} check node has connections to 0^{th}, 3^{rd} and 6^{th} variable nodes. The matrix H represents the encoding approach being adopted.

In wireless transmission, multiple-bit codeword is transmitted in form of analog signal after being encoded. Since the received signal may include noises, it is required to correctly decode the codeword in order to obtain correct codeword data. With respect to the decoded codeword, according to a multiplication rule of the matrix, if a kx1 “0” matrix can be obtained after multiplying the matrix H by a transposed matrix of the codeword, content of such codeword may be considered as the correct data.

During the decoding process of the LDPC code, multiple iterative operations are performed based on a decoding schedule according to the connection relation and the received signal in relative to the variable node. The connection relation basically includes a check to variable (C2V) message and a variable to check (V2C) message. For example, the codeword may be obtained when a convergence state is achieved after the multiple iterative operations are performed. Details regarding how to decode the codeword based on the decoding schedule according to the encoding relation in the matrix H belongs to the prior art, which is not repeated hereinafter. Further, the invention is not limited by specific decoding mechanism being used.

The invention intends to provide the planning of the decoding schedules required for decoding LDPC code. From a wider perspective, the feature proposed by the invention is to include a plurality of decoding attempts in the decoding process of the LDPC code. As a result, a faster convergence speed may be obtained by using different decoding schedules in the two adjacent decoding attempts, or a higher throughput may be obtained within the same number of iterations.

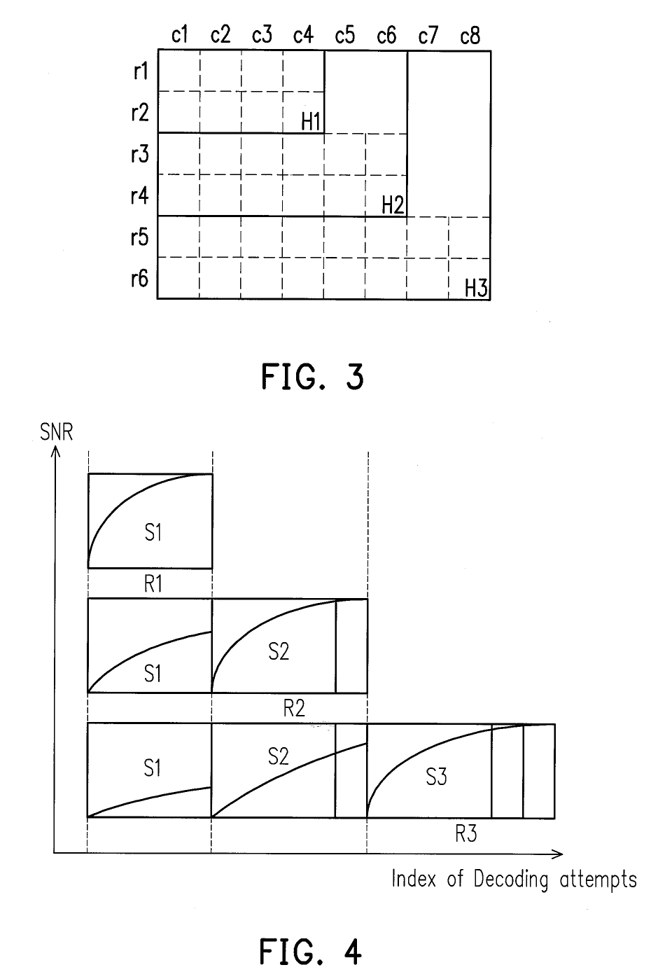

The decoding approach adopted by the invention includes, for example, a layered belief propagation (LBP) operation or a shuffled belief propagation (SBP) operation. FIG. 3 is a schematic diagram illustrating a general planning of the LDPC matrix according to an embodiment of the invention. In the matrix H, a sequence of one column is represented by respective one of r1 to r6, and a sequence of one row is represented by respective one of c1 to c8. The belief propagation is a method used to divide the propagation into multiple layers, and transfer the decoding messages according a sequence of the layers. Each of said layers can include one or more rows. In other words, the layered belief propagation (LBP) is to transfer the decoding messages according to a sequence of the rows in the parity check matrix. On the other hand, the shuffled belief propagation (SBP) is to transfer the decoding messages according to a sequence of the columns in the parity check matrix.

Taking one specific matrix H for example, according to a size of a code rate R, the specific matrix H is divided into different sub matrices corresponding to different code rates. For example, the matrix may be divided into three sub matrices H1, H2 and H3 in correspondence to code rates R1, R2 and R3. As for the definition of the code rate, for a k-bit matrix H (n, k) encoded with use of n-bit, a value of the code rate of said matrix is k/n.

As shown in FIG. 3, an example of the LDPC matrix H of a rate-compatible LDPC code is provided. The code rates of H1, H2 and H3 are R1, R2 and R3 respectively, where R1>R2>R3. H3 includes eight columns and six rows, and H1 includes four columns and two rows. If the schedule of the LBP is adopted, multiple iterations may be performed with the decoding schedule of {r1, r2, r1, r2 . . . } for decoding H1 and the decoding schedule of {r1, r2, r3, r4, r5, r6, r1, r2 . . . } for decoding H3. If the schedule of the SBP is adopted, multiple iterations may be performed with the decoding schedule of {c1, c2, c3, c4, c1, c2 . . . } for decoding H1 and the decoding schedule of {C1, c2, c3, c4, c5, c6, c7, c8, c1, c2 . . . } for decoding H3.

The sub matrix with higher code rate, such as the matrix H1, is generally adopted first for decoding. If data of the matrix H1 cannot be decoded, the matrix with lower code rate is then adopted. In general, if the signal includes fewer noises, it means that data carried by such signal can be easily recognized. As such, the codeword may be decoded simply by adopting the matrix H1 with high code rate. Nonetheless, it is still necessary to perform the multiple iterative operations. In the traditional approach, each of the decoding attempts adopts the same schedule. For example, if the first decoding attempt adopts the schedule of the LBP for decoding, the schedule of the LBP will also be used in each of subsequent decoding attempts.

However, the invention proposes to adopt use of different decoding schedules in different decoding attempts. For example, the sequence for decoding H1 may adopt {r1, r2, r1, r2 . . . } of the LBP while the sequence for decoding H3 may adopt {c1, c2, c3, c4, c5, c6, c7, c8, c1, c2 . . . } of the SBP instead. In other words, a plurality of decoding attempts is performed according to the LDPC matrix within a predetermined number of decoding attempts. The plurality of decoding attempts at least includes a first decoding attempt with use of a first decoding schedule and a second decoding attempt with use of a second decoding schedule. The second decoding attempt is adjacently subsequent to the first decoding attempt, and the first decoding attempt is not included in the second decoding attempt.

However, it is not intended to limit such distinct decoding attempts of the invention only to be achieved by lowering the code rate. For example, it can also be achieved by changing the decoding schedule in the adjacent iterative operations with the same code rate. Another embodiment is provided for further description, in which it is not intended to limit changing of the decoding sequence only to be achieved by switching between LBP and the SBP. Rather, the sequence for layering in the LBP may be changed. For example, if {r1, r2, r3, r4, r1, r2 . . . } is originally used for decoding H2, it is expected that {r1, r2, r3, r4, r5, r6, r1, r2 . . . } will be used for decoding H3 as in the traditional approach. However, it also satisfies the method of the invention for changing the decoding sequence if the schedule for decoding H3 may be changed to {r3, r2, r1, r4, r6, r5, r3, r2 . . . } according to the method of the invention.

Again, from another wider perspective, in the decoding process of one rate-compatible LDPC code, multiple decoding attempts may be included. Each of the decoding attempts may use a specific decoding schedule. For example, S1, S2, . . . Sk may be used to denote the decoding schedules used in the first, the second, . . . the kth decoding attempts, respectively. For example, when the LBP is used, what included in Sk is a sequence of the rows in the check matrix. In the example of FIG. 3, S1={r1, r2}, S2={r1, r2, r3, r4}. If the SBP is adopted, S1={c1, c2, c3, c4}. In the traditional decoding process, the previous decoding schedule is usually included in the next decoding sequence. For example, when the LBP is used for decoding the embodiment of FIG. 3, S2={S1, r3, r4}, where S1 represents {r1, r2}. In a more general expression, the traditional decoding schedule may be written as S(k−1)^{∈}Sk. However, in the method proposed by the invention, the next decoding schedule does not include the previous decoding schedule, namely, S(k−1)^{∉}Sk.

According to an embodiment of the invention, the decoding schedule may be randomly changed based on the same concept. Nonetheless, the decoding schedule may also be determined by using other estimation mechanisms in order to search for a more preferred decoding schedule. For example, in the variable decoding schedule “H.-C. Lee and Y.-L. Ueng, “Incremental Decoding Schedules for Puncture-based Rate-compatible LDPC codes,” accepted by IEEE VTC2016-Spring” published the inventors of this invention, the sequence used in each decoding attempt is designed by using the maximum mutual information increase (M²I²) algorithm proposed in the documentation “LDPC decoding scheduling for faster convergence and lower error floor,” IEEE Trans. on Commun., vol. 62, no. 9, pp. 3104-3113, September 2014”. Such method also satisfies the principle of aforesaid S(k−1)^{∉}Sk. Detailed description regarding the maximum mutual information increase (M²I²) algorithm may refer to documentation of the same, which is not repeated hereinafter.

However, it should be noted that, in the M²I² algorithm, the S/N ratio (SNR) is a control parameter capable of changing to a different decoding schedule being estimated. The SNR is, for example, a S/N ratio provided by the channel environment. For the decoding attempt S1, the S/N ratio is E_{S1}/N₀ where E_{S1} the energy and N₀ is the noise.

In addition, if different code rates are adopted in different decoding attempts, because condition of the SNR will change, a different decoding schedule not including the previously-estimated decoding schedule will be generated naturally through the M²I²-based operation. This situation also satisfies the technical feature of S(k−1)^{∉}Sk in the invention.

In view of the simulation result, it can be further understood that, the method used for decoding the rate-compatible LDPC code is capable of significantly increasing the throughput within a limited number of iterations. In each decoding attempt, in addition to the M²I² algorithm, the sequence of the decoding attempts may also be designed by using other methods or even randomly arranged. It falls within the general scope of the invention for which protection is sought as long as S(k−1)^{∉}Sk.

Accordingly, the invention includes use different decoding sequences in the two consecutive decoding attempts. This is achievable through various methods. For example, if the K^{th} decoding sequence is denoted by Sk, S(k−1)^{∉}Sk. As another example, when the LBP is used, what included in Sk is a sequence of the rows in the check matrix. As another example, when the SBP is used, what included in Sk is a sequence of the columns in the check matrix. As another example, the method for designing the decoding sequence is not particularly limited, but can be randomly selected. As yet another example, it falls within the protection scope of the present application as long as the result obtained by the design using the M²I² algorithm is S(k−1)^{∉}Sk. As another example, with the assistance of Incremental Decoding Schedules, a more efficient decoding schedule may be obtained

FIG. 4 is a schematic diagram illustrating a mechanism of resetting each time in a M²I²-based decoding schedule adopted for decoding LDPC code according to an embodiment of the invention. Referring to FIG. 4, three decoding attempts S1, S2 and S3 are constructed by using the M²I² algorithm according to the code rates R1, R2 and R3. Initial data is reset each time for each of the code rates R1, R2 and R3. Accordingly, because each time the code rate restarts the construction, the estimations for the three decoding attempts S1, S2 and S3 are independently performed without relating to one another. In other words, the operation performed each time begins with an initial state reset to zero. As a result, the present embodiment is more time-consuming.

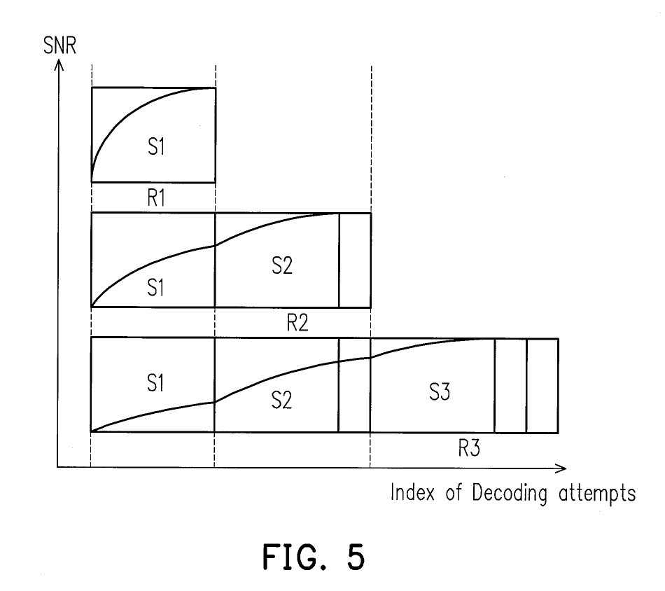

FIG. 5 is a schematic diagram illustrating a mechanism of incremental decoding schedules in a M²I²-based decoding schedule adopted for decoding the LDPC code according to an embodiment of the invention. Referring to FIG. 5, three decoding attempts S1, S2 and S3 are constructed by using the M²I² algorithm according to the code rates R1, R2 and R3. In the present embodiment, taking the operations of the code rates R2 and R3 for example, although an effective decoding schedule may still not be obtained as the result, data obtained by the current operation of the code rate will all be kept to serve as the initial data for estimating in the next code rate. Taking the condition at the second case for example, a successful decoding cannot be achieved since the decoding attempt S1 estimated by using the code rate R1 has a convergence value less than 1, and thus the code rates R2 is used for the estimation instead. In this case, although the effective decoding schedule cannot be obtained as the result of the decoding attempt S1, the result of such operation will be used as the initial condition for the decoding attempt S2, to accelerate convergence speed. The difference between the effects of FIG. 4 and FIG. 5 has been described in detail in aforementioned documentation, which is not repeated hereinafter.

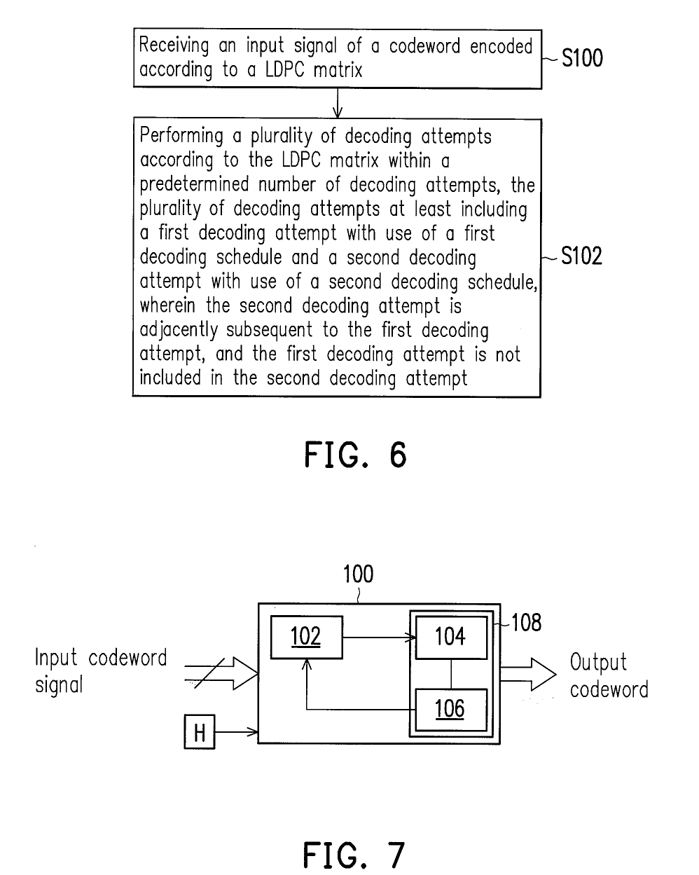

FIG. 6 is a flowchart of the decoding method for LDPC code according to an embodiment of the invention. Referring to FIG. 6, according to the foregoing description of the invention, a decoding method for LDPC code includes the following. In step S100, an input signal of a codeword encoded according to a LDPC matrix is received. In step S102, the codeword is decoded according a planned decoding schedule. A plurality of decoding attempts is performed according to the LDPC matrix within a predetermined number of decoding attempts. The plurality of decoding attempts at least includes a first decoding attempt with use of a first decoding schedule and a second decoding attempt with use of a second decoding schedule. The second decoding attempt is adjacently subsequent to the first decoding attempt, and the first decoding attempt is not included in the second decoding attempt.

FIG. 7 is a schematic diagram illustrating structure of the decoder for LDPC code according to an embodiment of the invention. Referring to FIG. 7, according to the foregoing description of the invention, a decoder 100 for LDPC code is configured to decode an input signal into a correct codeword according to a predetermined LDPC matrix. The decoder 10 includes a decoding unit 102, which is configured to decode the input signal into the correct codeword according the predetermined LDPC matrix H. A plurality of decoding attempts is performed according to the LDPC matrix within a predetermined number of decoding attempts, and The plurality of decoding attempts at least includes a first decoding attempt with use of a first decoding schedule and a second decoding attempt with use of a second decoding schedule. The second decoding attempt is adjacently subsequent to the first decoding attempt, and the first decoding attempt is not included in the second decoding attempt. The decoder 100 also includes a decoding schedule estimation unit 104, which is configured to generate and store a plurality of different decoding schedules according to the LDPC matrix for the decoding unit to obtain the first decoding schedule and the second decoding schedule. The decoder 100 further includes a storage unit 106, which is configured to store the decoding schedules obtained from and planned by the decoding schedule estimation unit 104 to be used by the decoding unit 102 for decoding.

The decoding method and the decoder proposed by the invention include decoding by using different decoding schedules in two consecutive decoding attempts in order to achieve the more efficient decoding operation. As for planning of the decoding schedules, the M²I²-based methods may further be used to conduct a more efficient planning. However, although it is described that the different decoding schedules are searched by using the M²I²-based operation, the invention is not limited thereto. The specific mechanism used to search for the decoding schedules is not particularly limited by the invention as long as the relation of S(k−1)^{∉}Sk can be included in the planning of decoding schedule of the invention.

Further to note, with the same aspect, all the foregoing methods as provided can also be applied to the base matrices for the photograph-based LDPC codes or QC-LDPC codes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A decoding method for low density parity check (LDPC) code, used to decode an input signal into a correct codeword according to a predetermined LDPC matrix, and comprising:
performing a plurality of decoding attempts according to the LDPC matrix within a predetermined number of decoding attempts, the plurality of decoding attempts at least including a first decoding attempt with use of a first decoding schedule and a second decoding attempt with use of a second decoding schedule,
wherein the second decoding attempt is adjacently subsequent to the first decoding attempt, and the first decoding attempt is not included in the second decoding attempt.

2. The decoding method for LDPC code according to claim 1, wherein the first decoding schedule is one of a layered belief propagation (LBP) sequence and a shuffled belief propagation (SBP) sequence, and the second decoding schedule is another one of the LBP sequence and the SBP sequence.

3. The decoding method for LDPC code according to claim 1, wherein the first decoding schedule and the second decoding schedule are both the LBP sequence but the a code rate of the second decoding schedule is lower than a code rate of the first decoding schedule.

4. The decoding method for LDPC code according to claim 1, wherein the first decoding schedule and the second decoding schedule are both the SBP sequence but the a code rate of the second decoding schedule is lower than a code rate of the first decoding schedule.

5. The decoding method for LDPC code according to claim 1, wherein the first decoding schedule and the second decoding schedule are different sequences determined according to different parameter conditions on basis of a maximum mutual information increase (M²I²) algorithm.

6. The decoding method for LDPC code according to claim 1, wherein the first decoding attempt and the second decoding attempt both reset an initial value of the codeword, or the subsequent second decoding attempt uses a result of the first decoding attempt as the initial value.

7. The decoding method for LDPC code according to claim 1, wherein a code rate of the second decoding attempt is lower than a code rate of the first decoding attempt.

8. The decoding method for LDPC code according to claim 1, wherein the first decoding schedule and the second decoding schedule are randomly arranged.

9. A decoder for low density parity check (LDPC) code, used to decode an input signal into a correct codeword according to a predetermined LDPC matrix, and comprising:
a decoding unit, configured to decode the input signal into the correct codeword according to the predetermined LDPC matrix, wherein a plurality of decoding attempts is performed according to the LDPC matrix within a predetermined number of decoding attempts, the plurality of decoding attempts at least including a first decoding attempt with use of a first decoding schedule and a second decoding attempt with use of a second decoding schedule, wherein the second decoding attempt is adjacently subsequent to the first decoding attempt, and the first decoding attempt is not included in the second decoding attempt; and
a decoding schedule estimation unit, configured to generate and store a plurality of different decoding schedules according to the LDPC matrix for the decoding unit to obtain the first decoding schedule and the second decoding schedule.

10. The decoder for LDPC code according to claim 9, wherein the first decoding schedule is one of a layered belief propagation (LBP) sequence and a shuffled belief propagation (SBP) sequence, and the second decoding schedule is another one of the LBP sequence and the SBP sequence.

11. The decoder for LDPC code according to claim 9, wherein the first decoding schedule and the second decoding schedule are both the LBP sequence but the a code rate of the second decoding schedule is lower than a code rate of the first decoding schedule.

12. The decoder for LDPC code according to claim 9, wherein the first decoding schedule and the second decoding schedule are both the SBP sequence but the a code rate of the second decoding schedule is lower than a code rate of the first decoding schedule.

13. The decoder for LDPC code according to claim 9, wherein the first decoding schedule and the second decoding schedule are different sequences determined according to different parameter conditions on basis of a maximum mutual information increase (M²I²) algorithm.

14. The decoder for LDPC code according to claim 9, wherein the first decoding attempt and the second decoding attempt both reset an initial value of the codeword, or the subsequent second decoding attempt uses a result of the first decoding attempt as the initial value.

15. The decoder for LDPC code according to claim 9, wherein a code rate of the second decoding attempt is lower than a code rate of the first decoding attempt.

16. The decoder for LDPC code according to claim 9, wherein the first decoding schedule and the second decoding schedule are randomly arranged.
